(19) United States
(12) Patent Application Publication
(10) Pub. No.: US 2006/0028129 A1
(43) Pub. Date: Feb. 9, 2006

(54) Organic electroluminescent device

(76) Inventors: Takahisa Sakakibara, Osaka (JP); Masakazu Sakata, Osaka (JP); Masaya Nakai, Anpachi-gun (JP); Hiroshi Kanno, Osaka (JP); Kazuki Nishimura, Osaka (JP); Hiroaki Izumi, Osaka (JP)

Correspondence Address: MCDERMOTT WILL & EMERY LLP, 600 13TH STREET, N.W., WASHINGTON, DC, 20005-3096, US

(21) Appl. No.: 11/091,344

(22) Filed: Mar. 29, 2005

(30) Foreign Application Priority Data
Mar. 29, 2004 (JP) 2004-096122

(51) Int. Cl. H05B 33/12

(52) U.S. Cl. 313/506; 428/690; 428/917; 313/504

(57) ABSTRACT

A hole injection electrode of a transparent conductive film such as indium-zinc-oxide is formed on a substrate, and a hole injection layer, a hole transport layer, a light emitting layer, and an electron transport layer are formed in this order on the hole injection electrode. Then, an electron injection electrode made of a material such as aluminum is formed on the electron transport layer. The hole injection layer is made for example of fluorocarbon (CFx). The thickness of the hole injection layer is preferably in the range from 30 Å to 90 Å.

### BACKGROUND OF THE INVENTION

1. Field of the Invention

The present invention relates to an organic electroluminescent device.

2. Description of the Background Art

An organic electroluminescent (hereinafter also referred to as “organic EL”) device has been expected as a new promising self-emitting device. The organic EL device has an organic layer including a hole transport layer, a light emitting layer, and an electron transport layer placed upon one another in this order between a hole injection electrode and an electron injection electrode. Note that a hole injection layer may be formed between the hole injection electrode and the hole transport layer, and an electron injection layer may be formed between the electron injection electrode and the electron transport layer.

In an organic EL device disclosed by Japanese Patent Laid-Open No. 2000-150171, a thin polymer film is formed as a hole injection layer on a hole injection electrode by high-frequency plasma polymerization. This improves the efficiency of hole injection from the hole injection electrode and the operation stability of the organic EL device.

As the hole injection electrode, an electrode material of a metal such as indium-tin-oxide (ITO) with a large work function is used, while as the electron injection electrode, an electrode material such as aluminum or lithium with a small work function is used.

Driving voltage is applied between the hole injection electrode and the electron injection electrode in the organic EL device, holes are injected from the hole injection electrode, and electrons are injected from the electron injection electrode. The injected holes and electrons move in the hole transport layer and the electron transport layer, respectively and are injected into the light emitting layer. The holes and electrons injected into the light emitting layer are recombined in the light emitting layer, so that excitons are formed and light is emitted.

In the above-described organic EL device, however, the driving voltage rises in a high temperature maintained state, which is a degradation in the characteristic. This prevents sufficient reliability from being obtained for the device.

### SUMMARY OF THE INVENTION

It is an object of the invention to provide an organic EL device that allows the rise in driving voltage in a high temperature maintained state to be reduced.

After various experiments carried out for finding the cause for the rise in the driving voltage when an organic EL device is kept at high temperature and much consideration given in connection with the experiment results, the inventors have found the following cause.

When driving voltage is applied to the organic EL device, a strong electric field is generated at the interface between the electrode and the organic layer. Reactive metal components in the electrode react with the strong electric field and is diffused into the organic layer to cause a chemical reaction with organic molecules in the organic layer. Consequently, the characteristic of the organic EL device is greatly affected.

When the organic EL device is continuously driven and exposed to the strong electric field in particular, the diffusion of the metal components from the electrode increases more.

The inventors have found that when an electrode of a particular material is used and a carrier injection layer containing a particular compound is formed on the electrode, the diffusion of the metal components from the electrode into the organic layer can be prevented and based on the findings, the inventors have conceived the following invention.

An organic electroluminescent device according to one aspect of the invention includes a first electrode, a carrier injection layer, an organic layer, and a second electrode placed in this order, the first electrode is made of a metal compound containing zinc, and the carrier injection layer includes at least one substance selected from the group consisting of fluorocarbon, copper phthalocyanine, and a starburst type organic compound.

In the organic electroluminescent device, the carrier injection layer including at least one substance selected from the group consisting of fluorocarbon, copper phthalocyanine, and a starburst type organic compound is formed on the first electrode, so that the diffusion of zinc atoms from the first electrode into the organic layer can be reduced when the organic electroluminescent device is maintained at high temperature for a long period. In this way, the rise in the driving voltage in a high temperature maintained state can be reduced.

The carrier injection layer may be made of fluorocarbon. In this way, the diffusion of zinc atoms from the first electrode into the organic layer can be more reduced when the organic electroluminescent device is maintained at high temperature for a long period.

The carrier injection layer made of fluorocarbon may have a film thickness in the range from 30 Å to 90 Å. In this way, the diffusion of zinc atoms from the first electrode into the organic layer can be more reduced when the organic electroluminescent device is maintained at high temperature for a long period The carrier injection layer may have a layered structure including a layer of copper phthalocyanine and a layer of fluorocarbon formed in this order on the first electrode. In this way, the diffusion of zinc atoms from the first electrode into the organic layer can sufficiently be reduced when the organic electroluminescent device is maintained at high temperature for a long period.

The layer of fluorocarbon may have a film thickness in the range from 10 Å to 90 Å. In this way, the diffusion of zinc atoms from the first electrode into the organic layer can be sufficiently reduced or prevented when the organic electroluminescent device is maintained at high temperature for a long period.

The first electrode may contain indium-zinc-oxide or zinc oxide. In this way, the cost is reduced, and the electrode surface can be more efficiently flattened.

An organic electroluminescent device according to another aspect of the invention includes a first electrode, an organic layer, and a second electrode placed in this order, and the first electrode is made of a metal compound containing zinc, and the depth of diffusion of a metal into the organic layer from the first electrode is at most one fifth of the film thickness of the organic layer when the organic electroluminescent device is kept at 85° C. for 40 hours.

In the organic electroluminescent device, the depth of diffusion of zinc atoms into the organic layer from the first electrode is at most one fifth of the film thickness of the organic layer when the organic electroluminescent device is kept at 85° C. for 40 hours, so that the rise in the driving voltage in a high temperature maintained state can be reduced.

The diffusion depth may be at most one tenth of the film thickness of the organic layer. In this way, the rise in the driving voltage in a high temperature maintained state can be even more reduced.

The diffusion depth may be obtained by secondary ionization mass spectrometer. In this way, the depth of diffusion can be more precisely obtained.

According to the invention, the diffusion of zinc atoms from the first electrode into the organic layer can be reduced when the organic electroluminescent device is maintained at high temperature for a long period. Consequently, the rise in the driving voltage can be reduced in a high temperature maintained state.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of an example of an organic EL device according to a first embodiment of the invention;

FIG. 2 is a graph showing how to determine the presence/absence of diffusion of a metal component into an organic layer;

FIG. 3 is a schematic sectional view of an example of an organic EL device according to a second embodiment of the invention;

FIGS. 4 and 5 are graphs showing results of measuring by SIMS for organic EL devices according to examples of the invention; and

FIG. 6 is a graph showing a result of measuring by SIMS for an organic EL device according to a comparative example.

### DESCRIPTION OF THE PREFERRED EMBODIMENTS

Now, an organic electroluminescent (hereinafter referred to as “organic EL”) device according to the invention will be described in conjunction with the accompanying drawings.

### First Embodiment

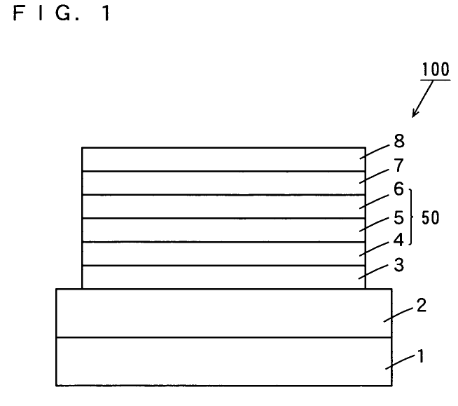

FIG. 1 is a schematic sectional view of an example of an organic EL device according to a first embodiment of the invention.

When the organic EL device 100 shown in FIG. 1 is produced, a hole injection electrode 2 made of a transparent conductive film such as indium-zinc-oxide (IZO) is formed on a substrate 1, and a hole injection layer 3, a hole transport layer 4, a light emitting layer 5, and an electron transport layer 6 are formed in this order on the hole injection electrode 2. An electron injection layer 7 for example of lithium fluoride and an electron injection electrode 8 for example of aluminum is then formed in this order on the electron transport layer 6. Note that the substrate 1 is a transparent substrate made of a material such as glass and plastic.

The hole injection layer 3 is made for example of fluorocarbon (CFx). The hole transport layer 4 is made of an organic material such as N,N′-Di(naphthalene-1-yl)-N,N′-diphenyl-benzidine (abbreviated as “NPB”). The hole transport layer 4 is for example as thick as 1500 Å.

The light emitting layer 5 is made for example of tert-butyl substituted dinaphthyl anthracene (abbreviated as “TBADN”). Note that the light emitting layer 5 is doped with 1.0 wt % perylene. The light emitting layer 5 emits blue light. The light emitting layer 5 is for example as thick as 400 Å.

The electron transport layer 6 is made for example of Tris(8-hydroxyquinolinato)aluminum (abbreviated as “Alq”). The electron transport layer 6 is for example as thick as 100 Å.

The electron injection layer 7 is for example as thick as 10 Å, and the electron injection electrode 8 is for example as thick as 2000 Å.

According to the embodiment, the hole injection layer 3 made of fluorocarbon is formed on the hole injection electrode 2. In this way, if the organic EL device is kept at high temperature (such as 85° C.) for a long period (such as 40 hours), the diffusion of metal components (mainly zinc (Zn) atoms) from the hole injection electrode 2 into an organic layer 50 can be reduced. Consequently, the rise in the driving voltage in a high temperature maintained state can be reduced.

The hole injection layer 3 preferably has a thickness in the range from 30 Å to 90 Å. In this way, when the organic EL device is kept at high temperature for a long period, the diffusion of the metal components from the hole injection electrode 2 into the organic layer 50 can be even more reduced.

In the organic EL device 100 according to the embodiment, the depth of the diffusion of the metal components from the hole injection electrode 2 into the organic layer 50 after the organic EL device is kept at 85° C. for 40 hours is not more than one fifth of the thickness of the organic layer 50, so that the rise in the driving voltage in a high temperature maintained state can be reduced.

In addition, when the depth of the diffusion of the metal components from the hole injection electrode 2 into the organic layer 50 after the organic EL device is kept at 85° C. for 40 hours is not more than one tenth of the thickness of the organic layer 50, the rise in the driving voltage in a high temperature maintained state can be more reduced.

Now, how to determine whether the metal components from the hole injection electrode 2 has diffused in the organic layer 50 before and after heating according to the embodiment and the following second embodiment will be described.

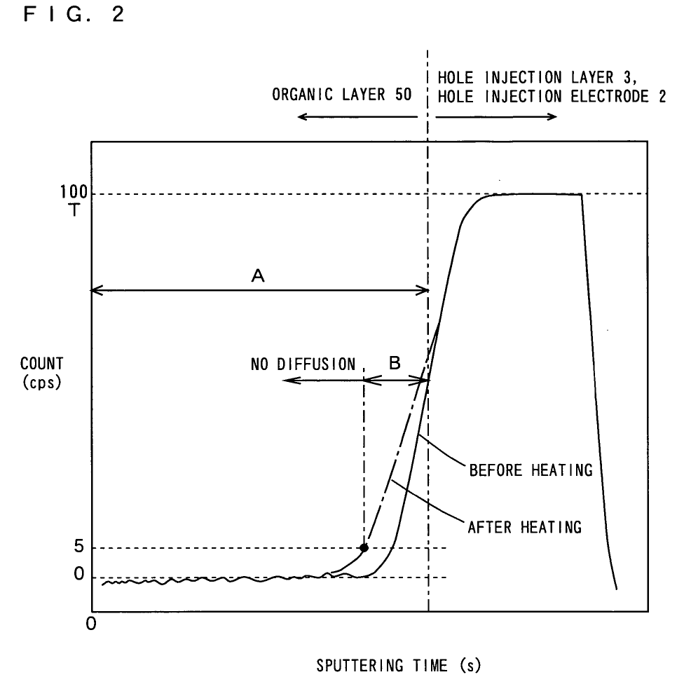

FIG. 2 shows how to determine the presence/absence of the diffusion of the metal components into the organic layer 50. Note that according to the embodiment, secondary ionization mass spectrometer (SIMS) is applied for determining the presence/absence of the Zn diffusion.

In the SIMS, for example a secondary ionization mass spectrometer analyzer ADEPT 1010 from ULVAC-PHI, INC. is used. As primary ions, for example cesium (Cs) is used, and the acceleration voltage is for example 2 KeV. The raster size is for example 400 μm square, and the injection angle of the primary ions is for example 60°.

As shown in FIG. 2, the abscissa represents sputtering time (sec), and the ordinate represents the count (cps) of the secondary ions of Zn.

The sputtering time refers to the time during which the ion beam (primary ions) is directed on the organic layer 50 in a vacuum. In this case, the ions are irradiated directly on the organic layer 50.

The count of secondary ions of Zn from the organic EL 100 before heating is denoted by the solid line, and the count after the heating is denoted by the chain-dotted line. Note that the position where the sputtering time is zero sec corresponds to the surface of the organic layer 50.

In the result before the heating denoted by the solid line in FIG. 2, the count of the secondary ions does not change much before a certain point in the sputtering time, and after the point, the count of the secondary ions abruptly increases. Thereafter, the count of the secondary ions stays at a prescribed level, and then after a certain point in the sputtering time, the count of the secondary ions abruptly decreases.

Here, it is assumed that the mid point between the point in the sputtering time where the count of the secondary ions starts to abruptly increase and the point where the count starts to stay at the prescribed level (hereinafter referred to as “interface sputtering time”) corresponds to the interface between the organic layer 50 and the hole injection layer 3.

As described above, the actual interface between the organic layer 50 and the hole injection layer 3 cannot be detected directly based on the result of SIMS, but when the above-described interface sputtering time is defined as corresponding to the interface between the organic layer 50 and the hole injection layer 3, the depth of Zn diffusion in the organic layer 50 after heating the organic EL device 100 can be detected.

In the result after the heating denoted by the chain-dotted line in FIG. 2, the background level during the period from the start of ion irradiation to a certain point in the sputtering time is 0%. The level of the count of the secondary ions staying substantially at the fixed level after the abrupt increase in the count of the secondary ions in the organic layer 50 is defined as 100%.

Here, based on the above-described definition, the sputtering time for the level of the count of secondary ions in the organic layer 50 to be 5% (hereinafter referred to as “diffusion determination sputtering time”) is determined. In this way, the difference B between the interface sputtering time and the diffusion determination sputtering time is calculated. The difference B corresponds to the depth of Zn diffusion into the organic layer 50.

More specifically, the process of calculating the value of the depth of Zn diffusion into the organic layer 50 is as follows. The ratio of the difference A between the time when ion irradiation starts (0 sec) and the interface sputtering time and the difference B is calculated. The difference A corresponds to the thickness of the organic layer 50.

When the thickness of the organic layer 50 is for example 2000 Å, and the difference B is one tenth of the difference A, the depth of the Zn diffusion into the organic layer 50 is 200 Å.

In this way, based on the result of SIMS, the depth of the Zn diffusion into the organic layer 50 can be calculated.

Note that according to the embodiment, fluorocarbon is used for the hole injection layer 3, but any other material such as copper phthalocyanine and a starburst type organic compound may be used for the hole injection layer 3.

The starburst type organic compound includes 4,4′,4″-tris [1-naphthyl(phenyl)amino]triphenylamine (abbreviated as “1-TNATA”) having the molecular structure as given in the formula (1), 4,4′,4″-tris[3-methylphenyl(phenyl)amino]triphenylamine (abbreviated as “MTDATA”) having the molecular structure given in the formula (2), triphenylaminetetramer (abbreviated as “TPTE”) having the molecular structure given in the formula (3), N,N′-diphenyl-N,N′-bis(4′-(N,N′-bis(naphth-1-yl)-amino)-biphenyl-4-yl)-benzidine (abbreviated as “NTPA”) having the molecular structure given in the formula (4), and N,N′-diphenyl-N,N′-bis(4′-(N,N′-bis(methylphenyl-1-yl)-amino)-phenyl-4-yl)-benzidine having the molecular structure given in the formula (5).

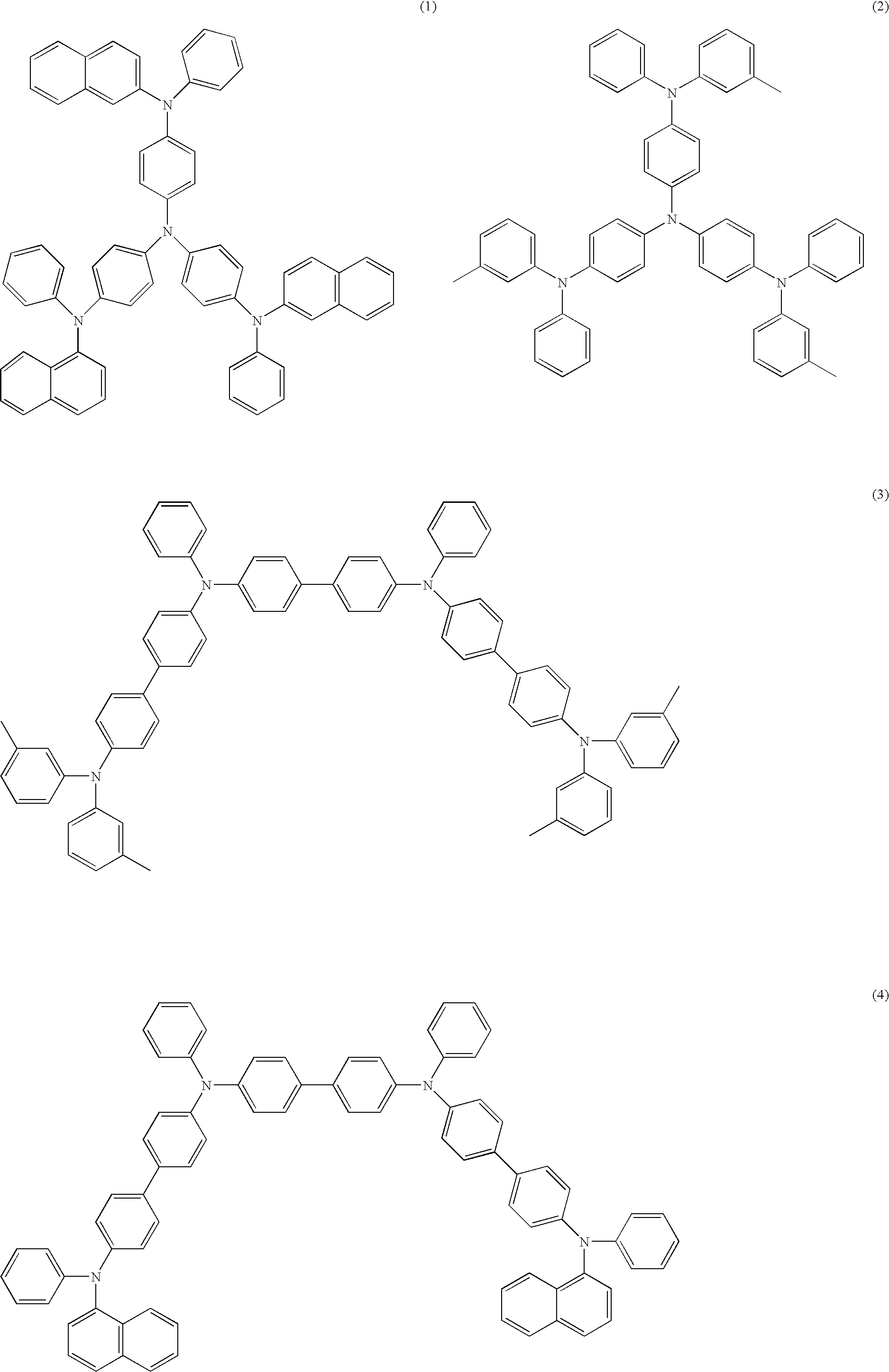

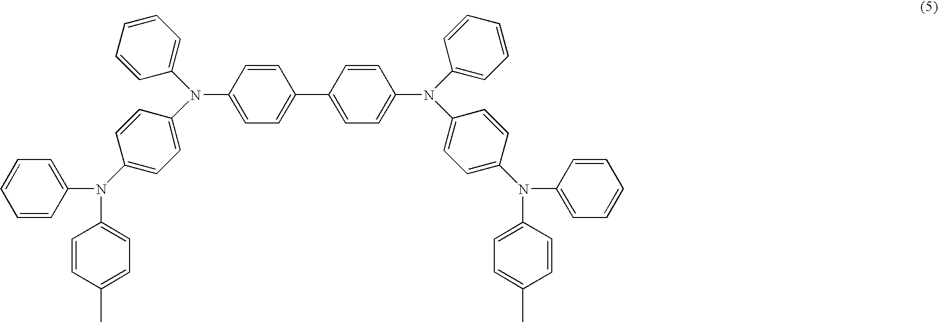

According to the embodiment, the hole injection electrode 2 corresponds to the first electrode, the hole injection layer 3 to the carrier injection layer, the organic layer 50 to the organic layer, and the electron injection electrode 7 to the second electrode.

### Second Embodiment

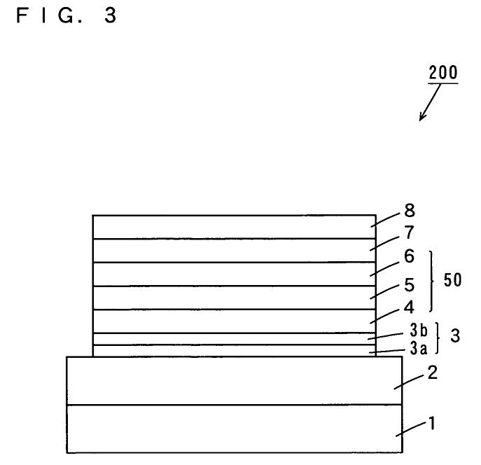

FIG. 3 is a schematic sectional view of an example of an organic EL device according to a second embodiment of the invention.

As shown in FIG. 3, the organic EL device 200 according to the embodiment is different from the organic EL device 100 according to the first embodiment in that the hole injection layer 3 has a layered structure including a first injection layer 3a and a second injection layer 3b formed on the first injection layer 3a.

The hole injection layer 3a in the hole injection layer 3 is made for example of copper phthalocyanine. The second injection layer 3b in the hole injection layer 3 is made for example of fluorocarbon.

According to the embodiment, the first injection layer 3a of copper phthalocyanine and the second injection layer 3b of fluorocarbon formed on the first injection layer 3a are formed as the hole injection layer 3 on the hole injection electrode 2. In this way, when the organic EL device is kept at high temperature (such as 85° C.) for a long period (such as 40 hours), the diffusion of metal components (mainly zinc (Zn) atoms) from the hole injection electrode 2 into the organic layer 50 can be reduced. Consequently, the rise in the driving voltage can be reduced in a high temperature maintained state.

The thickness of the second injection layer 3b made of fluorocarbon is preferably in the range from 10 Å to 90 Å. In this way, in a high temperature maintained state, the diffusion of the metal components from the hole injection electrode 2 into the organic layer 50 can be reduced more.

When the organic EL device 200 according to the embodiment is kept at 85° C. for 40 hours, and the depth of the diffusion of the metal components from the hole injection electrode 2 into the organic layer 50 is not more than one fifth of the thickness of the organic layer 50, the rise in the driving voltage in a high temperature maintained state can be reduced.

Furthermore, when the organic EL device is kept at 85° C. for 40 hours, and the depth of diffusion of the metal components from the hole injection electrode 2 into the organic layer 50 is not more than one tenth of the thickness of the organic layer 50, the rise in the driving voltage in a high temperature maintained state can be more reduced.

### EXAMPLES

Now, inventive examples and a comparative example will be described in conjunction with the drawings.

In the following Examples 1 and 2 and Comparative Example, a prescribed organic EL device was heated at 85° C. for 40 hours, the driving voltage for the organic EL device before and after the heating was measured, and evaluation according to secondary ionization mass spectrometer (SIMS) was carried out in order to determine the presence/absence of the diffusion of Zn from the hole injection electrode 2 into the organic layer 50.

### Example 1

The structure of the organic EL device according to Example 1 is the same as that of the organic EL device according to the first embodiment. The thickness of the hole injection layer 3 of fluorocarbon was 70 Å.

When the current before the heating was 20 mA/cm², the driving voltage (hereinafter referred to as “initial voltage”) for the organic EL device 100 was 6.4 V and the driving voltage for the organic EL device after the heating 6.8 V. Therefore, the rise in the driving voltage for the organic EL device 100 after the heating was 0.4 V.

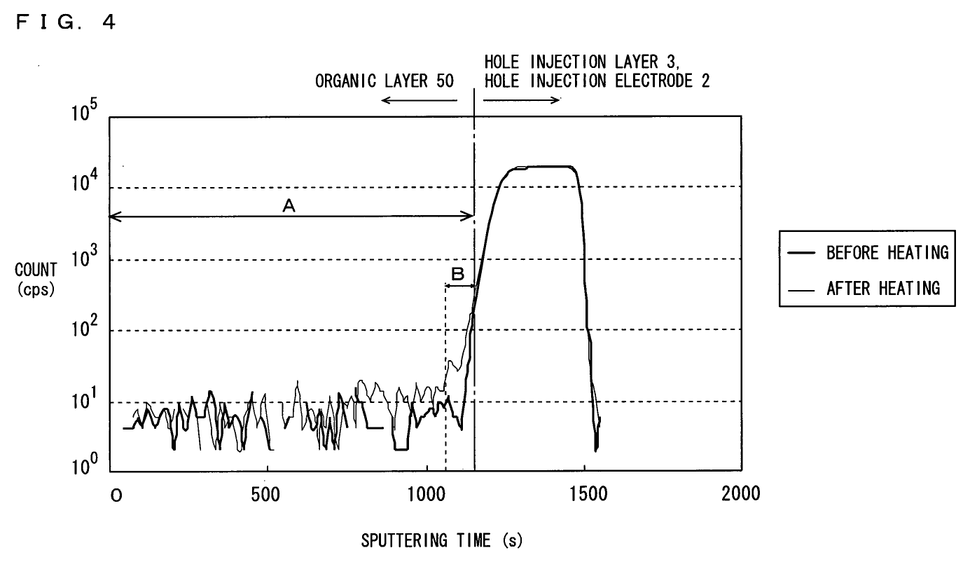

FIG. 4 is a graph showing a result of measuring by SIMS for the organic EL device 100 according to Example 1.

As shown in FIG. 4, it was found that the difference B corresponding to the depth of the diffusion of Zn into the organic layer 50 in the organic EL device 100 after the heating was not more than one tenth of the difference A corresponding to the thickness of the organic layer 50 and the Zn diffusion into the organic layer 50 was reduced.

### Example 2

The structure of an organic EL device according to Example 2 is the same as that of the organic EL device according to the second embodiment described above. The thickness of the first injection layer 3a of copper phthalocyanine in the hole injection layer 3 was 100 Å. The thickness of the second injection layer 3b of fluorocarbon in the hole injection layer 3 was 10 Å.

When the current before heating is 20 mA/cm², the initial voltage for the organic EL device 200 was 6.6 V, and the driving voltage for the organic EL device 200 after the heating was 6.8 V. Therefore, the rise in the value of the driving voltage for the organic EL device 200 after the heating was 0.2 V.

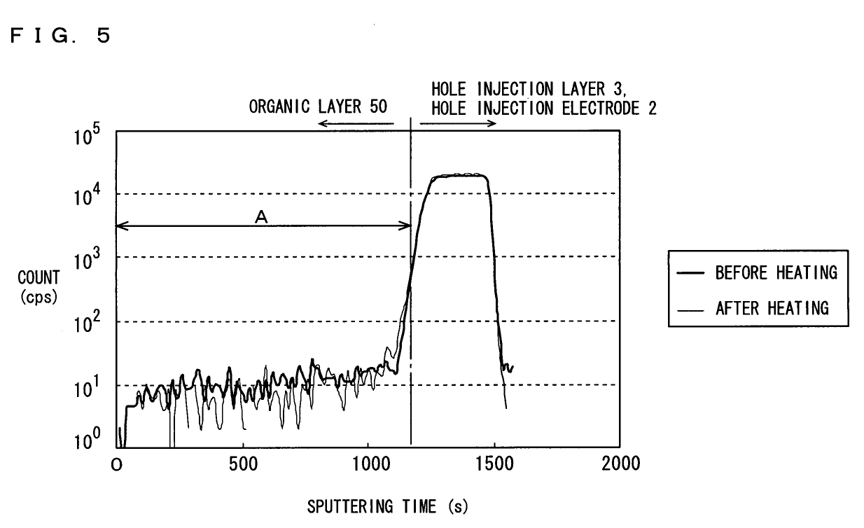

FIG. 5 is a graph showing a result of measuring by SIMS for the organic EL device 200 according to Example 2.

As shown in FIG. 5, in the organic EL device 200 after the heating, the difference B corresponding to the depth of diffusion of Zn into the organic layer 50 is zero, in other words, the Zn diffusion into the organic layer 50 was prevented.

### Comparative Example

The structure of an organic EL device according to Comparative Example is the same as that of the organic EL device according to the first embodiment. The thickness of the hole injection layer 3 of fluorocarbon was 10 Å.

When the current before the heating is 20 mA/cm², the initial voltage for the organic EL device 100 was 6.4 V, and the driving voltage for the organic EL device 100 after the heating was 8.9 V. Therefore, the rise in the value of the driving voltage for the organic EL device 100 after the heating was 2.5 V.

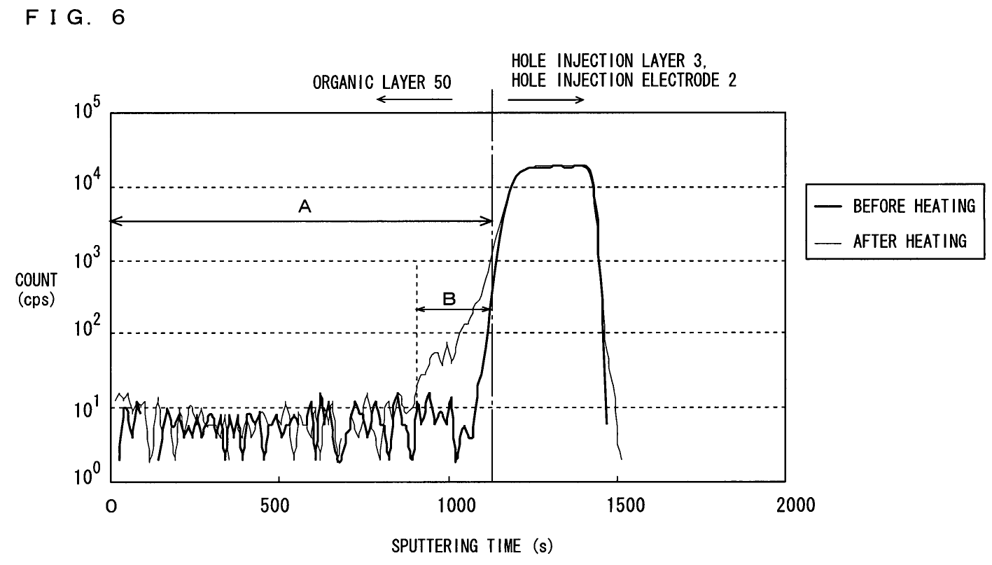

FIG. 6 is a graph showing a result of measuring by SIMS for the organic EL device 100 according to Comparative Example.

It was found that as shown in FIG. 6, in the organic EL device 100 after the heating, the difference B corresponding to the depth of Zn diffusion into the organic layer 50 was not less than one fifth of the difference A corresponding to the thickness of the organic layer 50, in other words, the Zn diffusion into the organic layer 50 was not reduced.

Evaluation

As in the foregoing, it has been found that the organic El device 100 including a hole injection layer 3 of fluorocarbon having a thickness in the range from 30 Å to 90 Å effectively reduces the Zn diffusion into the organic layer 50.

It has also been found that the organic EL device 200 including a hole injection layer 3 having a layered structure including the first and second injection layers 3a and 3b further reduces the Zn diffusion into the organic layer 50. It has also been found that in this case when the second injection layer 3b has a thickness of at least 10 Å, the Zn diffusion can be sufficiently reduced or prevented.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An organic electroluminescent device comprising a first electrode, a carrier injection layer, an organic layer, and a second electrode placed in this order, wherein
said first electrode is made of a metal compound containing zinc, and
said carrier injection layer comprises at least one substance selected from the group consisting of fluorocarbon, copper phthalocyanine, and a starburst type organic compound.

2. The organic electroluminescent device according to claim 1, wherein
said carrier injection layer is made of fluorocarbon.

3. The organic electroluminescent device according to claim 2, wherein
said carrier injection layer made of fluorocarbon has a film thickness in the range from 30 Å to 90 Å.

4. The organic electroluminescent device according to claim 1, wherein
said carrier injection layer has a layered structure including a layer of copper phthalocyanine and a layer of fluorocarbon formed in this order on said first electrode.

5. The organic electroluminescent device according-to claim 4, wherein
said layer of fluorocarbon has a film thickness in the range from 10 Å to 90 Å.

6. The organic electroluminescent device according to claim 1, wherein
said first electrode comprises indium-zinc-oxide or zinc oxide.

7. An organic electroluminescent device comprising a first electrode, an organic layer, and a second electrode placed in this order, wherein
said first electrode is made of a metal compound containing zinc, and
the depth of diffusion of a metal into the organic layer from said first electrode is at most one fifth of the film thickness of said organic layer when the organic EL device is kept at 85° C. for 40 hours.

8. The organic electroluminescent device according to claim 6, wherein
said diffusion depth is at most one tenth of the film thickness of said organic layer.

9. The organic electroluminescent device according to claim 6, wherein
said diffusion depth is obtained by secondary ionization mass spectrometer.

10. The organic electroluminescent device according to claim 7, wherein
said first electrode contains indium-zinc-oxide or zinc oxide.
